(19) United States
(12) Patent Application Publication
(10) Pub. No.: US 2011/0248252 A1
(43) Pub. Date: Oct. 13, 2011

(54) ORGANIC EL ELEMENT AND METHOD FOR FABRICATING THE SAME

(76) Inventors: Yasuyuki Ohnishi, Osaka (JP); Yoshimasa Fujita, Osaka (JP); Hideki Uchida, Osaka (JP)

(21) Appl. No.: 13/139,857

(22) PCT Filed: Aug. 17, 2009
(86) PCT No.: PCT/JP2009/003913

§ 371 Date: Jun. 15, 2011

(30) Foreign Application Priority Data
Jan. 16, 2009 (JP) 2009-008167

(51) Int. Cl. H01L 51/52; H01L 51/56

(52) U.S. Cl. 257/40; 438/46; 257/E51.018; 257/E51.019

(57) ABSTRACT

An organic EL display element (1) includes: an insulating substrate (3); a first electrode (6) formed on the substrate (3); an organic layer (7) having an emitting layer, formed on the first electrode (6); and a second electrode (8) formed on the organic layer (7). A conductive member (2) made of a material higher in thermal conductivity and higher in electrical conductivity than the substrate (3) is formed on a surface (3a) of the substrate (3) opposite to the surface on which the first electrode (6) is formed.

### TECHNICAL FIELD

The present disclosure relates to an organic electroluminescence element (hereinafter referred to as an organic EL element) and a method for fabricating the same.

### BACKGROUND ART

In recent years, organic EL display devices have received attention as next-generation flat panel display devices. Since the organic EL display devices, which are self-luminous display devices, have excellent viewing angle characteristics, high visibility, and low power consumption and can be thinned, demands for such devices have been increasing.

An organic EL display device has a plurality of organic EL elements arranged in a predetermined array, and each of the organic EL elements has an anode as a first electrode formed on an insulating substrate, an organic layer having an emitting layer formed on the first electrode, and a cathode as a second electrode formed on the organic layer.

As a technique of forming an organic EL thin film used for the organic EL display device on a substrate, a vacuum evaporation method is generally known. In the vacuum evaporation method, first, the substrate is placed horizontally under vacuum with the surface thereof to be subjected to evaporation facing downward, and a metal mask is brought into close contact with this surface of the substrate. Thereafter, an evaporation material (i.e., an organic EL material) is evaporated from an evaporation source onto the substrate surface via openings of the mask having a predetermined pattern, thereby to form an organic EL thin film having the predetermined pattern on the substrate surface.

In general, when the degree of rectification of organic EL elements is low, a minute leakage current flows during application of a reverse bias. A crosstalk phenomenon occurs due to this leakage current, resulting in largely damaging the display quality.

In view of the above problem, there is proposed a method for fabricating an organic EL element directed to preventing occurrence of a crosstalk phenomenon to prevent degradation in display quality. More specifically, there is disclosed a method for fabricating an organic EL element, which uses a vacuum evaporation apparatus in formation of an organic EL thin film on a substrate. The vacuum evaporation apparatus has a substrate temperature control device that includes: a temperature sensor for controlling the temperature of the surface of the substrate on which the film is to be formed; and a heat dissipater/absorber. In this method for fabricating an organic EL element, the substrate temperature is controlled to 70° C. or less and the absolute value of the temperature change rate is controlled to 1.5° C./sec using the vacuum evaporation apparatus. It is argued that, by this method, organic EL elements having an excellent rectification characteristic can be fabricated, and also a display panel high in display quality without crosstalk can be fabricated (see Patent Document 1, for example).

### CITATION LIST

### Patent Document

PATENT DOCUMENT 1: Japanese Patent Publication No. P2001-85164

### SUMMARY OF THE INVENTION

### Technical Problem

The method for fabricating an organic EL element described in Patent Document 1 has the following problems. Even though having been controlled by this method, the substrate temperature rises, and the substrate has static electricity, during formation of a cathode as a second electrode by the vacuum evaporation method. Due to the rise in substrate temperature and the static electricity existing in the substrate, injection of a current from the organic layer into the cathode becomes insufficient in the fabricated organic EL elements. As a result, the drive voltage of the organic EL elements increases, and the luminous efficiency thereof decreases.

It is an objective of the present disclosure to provide an organic EL element of which the drive voltage can be reduced and of which the luminance efficiency can be enhanced, and a method for fabricating such an organic EL element.

### Solution to the Problem

To achieve the above objective, the organic EL element of the present disclosure includes: a substrate; a first electrode formed on the substrate; an organic layer having an emitting layer, formed on the first electrode; and a second electrode formed on the organic layer, wherein a conductive member made of a material higher in thermal conductivity and higher in electrical conductivity than the substrate is formed on a surface of the substrate opposite to a surface on which the first electrode is formed.

With the above configuration, during formation of the second electrode by a vacuum evaporation method, heat in the substrate is conducted to the conductive member, cooling the substrate by the conductive member. Thus, temperature rise in the substrate can be suppressed or reduced. Also, during formation of the second electrode by the vacuum evaporation method, since static electricity existing in the substrate is removed by the conductive member, making the substrate free of static electricity, influence of static electricity can be prevented. This facilitates current injection from the organic layer into the second electrode. Thus, the drive voltage of the organic EL element can be reduced, and also the luminous efficiency of the element can be improved.

Also, with the existence of the conductive member on the surface of the substrate, during injection of a current from the organic layer into the second electrode, the current density per unit area decreases, permitting dispersed injection of the current into the second electrode. Therefore, current-caused degradation is reduced, and as a result, the life of the organic EL element can be increased.

In the organic EL element of the present disclosure, the thermal conductivity may be 80 W/m·k or more and the electrical conductivity may be 8×10⁶/mΩ or more.

With the above configuration, the thermal conductivity and electrical conductivity of the conductive member can be made sufficiently higher than those of the substrate. It is therefore ensured that temperature rise in the substrate can be suppressed or reduced, and also influence of static electricity can be prevented, during formation of the second electrode by the vacuum evaporation method.

In the organic EL element of the present disclosure, the material may be metal.

With the above configuration, the thermal conductivity and electrical conductivity of the conductive member can be easily improved.

In the organic EL element of the present disclosure, the metal may be at least one kind selected from the group consisting of silver, copper, gold, aluminum, calcium, tungsten, magnesium, rhodium, iridium, sodium, molybdenum, ruthenium, zinc, cobalt, cadmium, nickel, osmium, lithium, indium, and iron.

With the above configuration, the conductive member can be formed of an inexpensive and versatile material.

The method for fabricating an organic EL element of the present disclosure is a method for fabricating an organic EL element including a first electrode, an organic layer having an emitting layer, and a second electrode formed in this order on a substrate, the method including the steps of: forming a conductive member on a surface of the substrate, the conductive member being made of a material higher in thermal conductivity and higher in electrical conductivity than the substrate; forming the first electrode on a surface of the substrate opposite to the surface on which the conductive member is formed; and forming the organic layer on the first electrode, and then forming the second electrode on the organic layer, by a vacuum evaporation method using a mask.

Accordingly, during formation of the second electrode by a vacuum evaporation method, heat in the substrate is conducted to the conductive member, cooling the substrate by the conductive member. Thus, temperature rise in the substrate can be suppressed or reduced. Also, during formation of the second electrode by the vacuum evaporation method, since static electricity existing in the substrate is removed by the conductive member, making the substrate free of static electricity, influence of static electricity can be prevented. This facilitates current injection from the organic layer into the second electrode. Thus, it is possible to provide an organic EL element of which the drive voltage can be reduced and of which the luminous efficiency can be improved.

Also, with the formation of the conductive member on the surface of the substrate, during injection of a current from the organic layer into the second electrode, the current density per unit area decreases, permitting dispersed injection of the current into the second electrode. Therefore, current-caused degradation is reduced, and as a result, the life of the organic EL element can be increased.

In the method for fabricating an organic EL element of the present disclosure, the thermal conductivity may be 80 W/m·k or more and the electrical conductivity may be 8×10⁶/mΩ or more.

Accordingly, the thermal conductivity and electrical conductivity of the conductive member can be made sufficiently higher than those of the substrate. It is therefore ensured that temperature rise in the substrate can be suppressed or reduced, and also influence of static electricity can be prevented, during formation of the second electrode by the vacuum evaporation method.

In the method for fabricating an organic EL element of the present disclosure, the material may be metal.

Accordingly, the thermal conductivity and electrical conductivity of the conductive member can be easily improved.

In the method for fabricating an organic EL element of the present disclosure, the metal may be at least one kind selected from the group consisting of silver, copper, gold, aluminum, calcium, tungsten, magnesium, rhodium, iridium, sodium, molybdenum, ruthenium, zinc, cobalt, cadmium, nickel, osmium, lithium, indium, and iron.

Accordingly, the conductive member can be formed of an inexpensive and versatile material.

### Advantages of the Invention

According to the present disclosure, it is possible to provide an organic EL element of which the drive voltage can be reduced and of which the luminous efficiency can be improved. Also, it is possible to provide an organic EL element of which the life can be increased.

### BRIEF DESCRIPTION OF THE DRAWINGS

FIG. 1 is a cross-sectional view of an organic EL element of an embodiment of the present disclosure.

FIG. 2 is a cross-sectional view illustrating the shape of a second electrode of the organic EL element of the embodiment of the present disclosure.

FIG. 3 is a cross-sectional view illustrating a method for fabricating the organic EL element of the embodiment of the present disclosure.

FIG. 4 is a cross-sectional view illustrating the method for fabricating the organic EL element of the embodiment of the present disclosure.

FIG. 5 is a cross-sectional view illustrating the method for fabricating the organic EL element of the embodiment of the present disclosure.

FIG. 6 is a cross-sectional view illustrating the method for fabricating the organic EL element of the embodiment of the present disclosure.

FIG. 7 is a cross-sectional view illustrating the method for fabricating the organic EL element of the embodiment of the present disclosure, which is particularly a view illustrating formation of a cathode as a second electrode.

### DESCRIPTION OF EMBODIMENTS

An embodiment of the present invention will be described hereinafter with reference to the drawings. It should be noted that the present disclosure is not limited to the following embodiment.

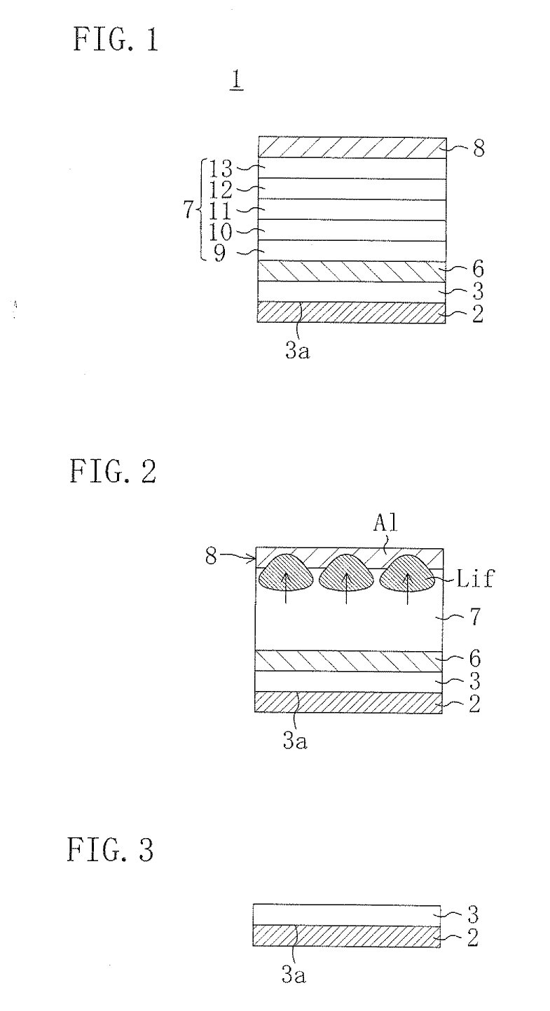

FIG. 1 is a cross-sectional view of an organic EL element of an embodiment of the present disclosure, and FIG. 2 is a cross-sectional view illustrating the shape of a second electrode of the organic EL element of the embodiment of the present disclosure.

The organic EL element 1 is used for displays of cellular phones, portable digital assistants (PDAs), TV sets, electronic books, monitors, electronic posters, watches, electronic shelf tags, emergency guidance, etc., for example.

As shown in FIG. 1, the organic EL element 1 includes: an insulating substrate 3; a first electrode 6 (anode) placed on a surface of the insulating substrate 3; an organic layer 7 placed on the surface of the first electrode 6; and a second electrode 8 (cathode) placed on the surface of the organic layer 7.

Also, as shown in FIG. 1, the organic layer 7 includes: a hole injection layer 8; a hole transport layer 10 formed on the surface of the hole injection layer 9; an emitting layer 11 formed on the surface of the hole transport layer 10 for emitting red light, green light, or blue light; an electron transport layer 12 formed on the surface of the emitting layer 11; and an electron injection layer 13 formed on the surface of the electron transport layer 12. The hole injection layer 9, the hole transport layer 10, the emitting layer 11, the electron transport layer 12, and the electron injection layer 13 are stacked one upon another sequentially, to form the organic layer 7. The organic layer 7 is not limited to the five-layer structure comprised of the hole injection layer 9, the hole transport layer 10, the emitting layer 11, the electron transport layer 12, and the electron injection layer 13. For example, it may be of a three-layer structure comprised of a hole injection/transport layer, an emitting layer, and an electrode transport/injection layer.

The substrate 3 has a function of securing the mechanical endurance of the organic EL element 1 and a function of blocking entering of water and oxygen into the organic EL element 1 from outside. The substrate 3 has a size of 100 to 3000 mm by 100 to 3000 mm and a thickness of 0.1 to 2 mm.

Examples of the substrate 3 include: glass substrates made of quartz glass, soda glass, alkali-free glass, etc.; ceramic substrates made of alumina, etc.; plastic substrates made of polyethylene terephthalate, etc.; substrates made of metal such as aluminum and iron one surface of which is coated with an insulating material such as SiO₂ (silica gel) and an organic insulating material; and substrates made of metal such as aluminum and iron the surface of which is subjected to insulation treatment by anodization, etc. On the substrate 3, formed normally are various interconnects for drive control of organic EL display and switching elements such as thin film transistors (TFTs).

The first electrode 6 is formed of a conductive material and has a thickness of 50 to 500 nm, for example. The first electrode 6 has a function of injecting holes into the organic layer 7.

Examples of the material for forming the first electrode 6 include metal materials such as silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The first electrode 6 may also be formed of any of alloys of magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), and lithium fluoride (LiF)/calcium (Ca)/aluminum (Al). The first electrode 6 may further be formed of any of conductive oxides such as tin oxide (SnO), zinc oxide (ZnO), indium tin oxide (ITO), and indium zinc oxide (IZO).

It is preferable that the first electrode 6 is formed of a material large in work function from the standpoint of the ability of improving the efficiency of injecting holes into the organic layer 7. Examples of such a material large in work function include gold (Au), nickel (Ni), indium tin oxide (ITO), and indium zinc oxide (IZO).

When the organic EL element 1 is of a bottom emission structure in which light is output from the side of the organic layer 7 facing the first electrode 6, the first electrode 6 is preferably formed of a light transmissive or semi-transmissive material such as ITO. When the organic EL element 1 is of a top emission structure in which light is output from the side of the organic layer 7 opposite to the side facing the first electrode 6, the first electrode 6 is preferably formed of a light reflective material such as aluminum.

The first electrode 6 may be formed of a plurality of layers each made of any of the above conductive materials.

The hole injection layer 9, also called as an anode buffer layer, has a function of bringing the energy level of the organic layer 7 close to that of the first electrode 6, to improve the efficiency of injecting holes from the first electrode 6 into the emitting layer 11. Examples of the material for forming the hole injection layer 9 include: benzine, styrylamine, triphenylamine, porphyrin, triazole, imidazole, oxadiazole, polyarylalkane, phenylenediamine, arylamine, oxazole, anthracene, fluorenone, hydrazone, stilbene, triphenylene, and azatriphenylene; derivatives thereof; and heterocyclic conjugated monomers, oligomers, and polymers such as polysilane-based compounds, vinylcarbazole-based compounds, thiophene-based compounds, and aniline-based compounds. The hole injection layer 9 has a thickness of 10 to 300 nm.

The hole transport layer 10 has a function of improving the efficiency of transporting holes from the first electrode 6 to the organic layer 7. Examples of the material for forming the hole transport layer 10 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide. The hole transport layer 10 has a thickness of 10 to 300 nm.

The emitting layer 11 is a region into which holes and electrons are injected from the first electrode 6 and the second electrode 8, respectively, during application of a voltage between the electrodes and in which holes and electrodes recombine. The emitting layer 11 has a function of recombining holes injected from the first electrode 6 and the electrons injected from the second electrode 8 to allow emission of light. The emitting layer 11 is formed of a material high in light emitting efficiency, such as organic materials including low-molecular fluorescent pigments, fluorescent polymers, and metallic complexes. More specifically, examples of the material for fowling the emitting layer 11 include: low-molecular compounds such as naphthalene derivatives, anthracene derivatives, metal oxynoid compounds [8-hydroxyquinoline metallic complexes], diphenylethylene derivatives, vinylacetone derivatives, triphenylamine derivatives, butadiene derivatives, coumalin derivatives, benzoxazole derivatives, oxadiazole derivatives, oxazole derivatives, benzimidazole derivatives, thiadiazole derivatives, benzthiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, acridine derivatives, phenoxazone, quinacridone derivatives, and rubrene; and polymeric compounds such as poly-p-phenylenevinylene and polysilane. The emitting layer 11 has a thickness of 10 to 300 nm.

Any of hole transport materials, electron transport materials, additives (donors, acceptors, etc.), luminescent dopants, etc. may be added to the emitting layer 11. These addition materials may be added in a dispersed state in polymeric materials (resins for binding) and inorganic materials. Note that, in the case of addition of a luminescent dopant, the dopant is preferably added in a dispersed state in a host material from the standpoint of the luminous efficiency and the life.

Examples of the luminescent dopant include aromatic dimethylidene derivatives such as 4,4′-bis(2,2′-diphenylvinyl)-biphenyl (DPVBi) and 4,4′-bis[2-{4-(N,N-diphenylamino)phenyl}vinyl]biphenyl (DPAVBi), styryl derivatives, coumalin derivatives such as perylene, iridium complexes, and coumalin 6, Lumogen F Red, dicyanomethylene pyran, phenoxazone, and polyphyllin derivatives. By selecting the kinds of the dopants appropriately, a red emitting layer that emits red color, a green emitting layer that emits green color and a blue emitting layer that emits blue color are obtained.

The electron transport layer 12, also called as a cathode buffer layer, has a function of transporting electrons injected from the second electrode 8 efficiently. Examples of the material for forming the electron transport layer 12 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxynoid compounds. The electron transport layer 12 has a thickness of 10 to 300 nm.

The electron injection layer 13 has a function of bringing the energy level of the organic layer 7 close to that of the second electrode 8, to improve the efficiency of injecting electrons from the second electrode 8 into the emitting layer 11. As a material for forming the electron injection layer 13, a metal having a work function as low as 4.0 eV or less can be used, including calcium (Ca), cerium (Ce), cesium (Cs), rubidium (Rb), strontium (Sr) barium (Ba), magnesium (Mg), and lithium (Li). When a polymeric organic emitting layer is used as the emitting layer, Ca and Ba, among others, are preferably used as the material for forming the electron injection layer 13. In general, to avoid alteration of the low-work-function metals due to oxygen and hydrogen, any of the following is suitably used for the electron injection layer 13: single-layer films of alloys of the low-work-function metals and comparatively chemically stable metals such as nickel (Ni), osmium (Os), platinum (Pt), palladium (Pd), aluminum (Al), silver (Ag), gold (Au), and rhodium (Rh), and multilayer films of a plurality of such materials; fluorides such as lithium fluoride (LiF), magnesium fluoride (MgF₂), calcium fluoride (CaF₂), strontium fluoride (SrF₂), and barium fluoride (BaF₂); oxides such as calcium oxide (CaO) and strontium oxide (SrO); and carbonates such as calcium carbonate (CaCO₃) and barium carbonate (BaCO₃). Alternatively, as a layer serving as both the electron injection layer 13 and the second electrode 8, it is possible to use an organic material having an electron injection property, in which any of the above low-work-function metals is added as a dopant to an organic material such as CuPc. The electron injection layer 13 has a thickness of 0.1 to 100 nm.

The second electrode 8 is formed of a conductive material and has a thickness of 50 to 500 nm, for example. The second electrode 8 has a function of injecting electrons into the organic layer 7. The second electrode 8 may be smaller in area than the organic layer 7 or may be large enough to completely cover the organic layer 7.

As examples of the conductive material for the second electrode 8, materials similar to those for the first electrode 6 can be listed, for example.

The second electrode 8 may be formed of a multilayer film of a low-work-function layer made of a material low in work function and a comparatively chemically durable metal layer (e.g., Ca/Al, Ce/Al, Cs/Al, Ba/Al, etc.). The second electrode 8 may also be formed of any of alloys including materials low in work function (e.g., Ca:Al alloy, Mg:Ag alloy, Li:Al alloy, etc.), multilayer films of layers made of alkali metal fluorides and conductive layers (e.g. LiF/Al, LiF/Ca/Al, BaF₂/Ba/Al, etc.), transparent conductive oxides doped with materials low in work function (e.g., ITO:Cs IDIXO:Cs, SnO₂:Cs, etc.), multilayer films of layers made of transparent conductive oxides and layers made of materials low in work function (e.g., Ba/ITO, Ca/IDIXO, Ba/SnO₂, etc.) etc.

When the organic EL element 1 is of a top emission structure, the second electrode 8 is preferably formed of an extremely thin layer made of Al and Ag or a light transmissive or semi-transmissive material such as ITO. When the organic EL element 1 is of a bottom emission structure, the second electrode 8 is preferably formed of a light reflective material such as aluminum.

The second electrode 8 may be formed of a plurality of layers each made of any of the above conductive materials.

In the organic EL element 1 having the configuration described above, when the TFT formed on the substrate 3 is turned on, holes are injected into the organic layer 7 from the first electrode 6 and also electrons are injected from the second electrode 8. Such holes and electrons recombine in the organic layer 7, and resultantly released energy excites the luminescent material of the emitting layer 11. The excited luminescent material emits fluorescence and phosphorescence when it resumes its ground state from the excited state. Such fluorescence and phosphorescence are output as light emission from the organic layer 7, whereby a predetermined image is displayed.

Although the first electrode 6 is configured to serve as the anode and the second electrode 8 as the cathode in this embodiment, the organic EL element may be of an inverted structure in which the first electrode 6 serves as the cathode and the second electrode 8 as the anode. In this case, electrons and holes are to be injected into the organic layer 7 from the first electrode 6 and the second electrode 8, respectively, and recombine with each other, to allow the organic layer 7 to emit light, whereby a predetermined image will be displayed.

A feature of this embodiment is that a conductive member 2 made of a material higher in thermal conductivity and higher in electrical conductivity than the substrate 3 is formed on a surface 3a of the substrate 3 opposite to the surface thereof on which the first electrode 6 is formed, as shown in FIG. 1.

With the above configuration, during formation of the cathode as the second electrode 8 by the vacuum evaporation method, heat in the substrate 3 is conducted to the conductive member 2, cooling the substrate 3 by the conductive member 2, and thus temperature rise in the substrate 3 can be suppressed or reduced. This facilitates injection of a current from the organic layer 7 into the second electrode 8. Thus, the drive voltage of the organic EL element 1 can be reduced, and the luminous efficiency thereof can be improved.

Also, during formation of the cathode as the second electrode 8 by the vacuum evaporation method, since static electricity existing in the substrate 3 is removed by the conductive member 2, making the substrate free of static electricity, influence of static electricity can be prevented. This facilitates injection of a current from the organic layer 7 into the second electrode 8. Thus, the drive voltage of the organic EL element 1 can be reduced, and the luminous efficiency thereof can be improved.

More specifically, assume that the second electrode 8 is to be formed of a multilayer film of a layer made of an alkali metal fluoride and a conductive layer (e.g., LiF/Al). By placing the conductive member 2 on the surface 3a of the substrate 3, during formation of the cathode as the second electrode 8 by the vacuum evaporation method, the substrate 3 is cooled by the conductive member 2 and also static electricity in the substrate 3 is removed by the conductive member 2 as described above. Therefore, LiF can be deposited into a round and large shape as shown in FIG. 2 without being affected by heat and static electricity. This increases the contact area of LiF with the organic layer 7, improving injection of a current from the organic layer 7 into the second electrode 8 (indicated by arrows in FIG. 2). As a result, the drive voltage of the organic EL element can be reduced, and the luminous efficiency thereof can be enhanced.

Moreover, since the contact area of LiF with the organic layer 7 increases by placing the conductive member 2 on the surface 3a of the substrate 3 as described above, the current density per unit area decreases during injection of a current from the organic layer 7 into the second electrode 8, permitting dispersed injection of the current into the second electrode 8. Therefore, current-caused degradation is reduced.

Any material can be used as the material for forming the conductive member 2 as far as it is higher in thermal conductivity and higher in electrical conductivity than the substrate 3. For example, the following metal materials can be suitably used: silver (electrical conductivity: 63×10⁶/mΩ, thermal conductivity: about 429 W/m·k), copper (electrical conductivity: about 59.6×10⁶/mΩ, thermal conductivity: about 401 W/m·k), gold (electrical conductivity: about 45.2×10⁶/mΩ, thermal conductivity: about 317 W/m·k), aluminum (electrical conductivity: about 37.7×10⁶/mΩ, thermal conductivity: about 237 W/m·k), calcium (electrical conductivity: about 29.8×10⁶/mΩ, thermal conductivity: about 201 W/m·k), tungsten (electrical conductivity: about 18.9×10⁶/mΩ, thermal conductivity: about 174 W/m·k), magnesium (electrical conductivity: about 22.6×10⁶/mΩ, thermal conductivity: about 156 W/m·k), rhodium (electrical conductivity: about 21.1×10⁶/mΩ, thermal conductivity: about 150 W/m·k), silicon (electrical conductivity: about 2.52×10⁶/mΩ, thermal conductivity: about 148 W/m·k), iridium (electrical conductivity: about 19.7×10⁶/mΩ, thermal conductivity: about 147 W/m·k), sodium (electrical conductivity: about 21×10⁶/mΩ, thermal conductivity: about 141 W/m·k), molybdenum (electrical conductivity: about 18.7×10⁶/mΩ, thermal conductivity: about 138 W/m·k), ruthenium (electrical conductivity: about 13.7×10⁶/mΩ, thermal conductivity: about 117 W/m·k), zinc (electrical conductivity: about 16.6×10⁶/mΩ, thermal conductivity: about 116 W/m·k), cobalt (electrical conductivity: about 17.2×10⁶/mΩ, thermal conductivity: about 100 W/m·k), cadmium (electrical conductivity: about 13.8×10⁶/mΩ, thermal conductivity: about 96.8 W/m·k), chromium (electrical conductivity: about 7.74×10⁶/mΩ, thermal conductivity: about 93.9 W/m·k), nickel (electrical conductivity: about 14.3×10⁶/mΩ, thermal conductivity: about 90.7 W/m·k), osmium (electrical conductivity: about 10.9×10⁶/mΩ, thermal conductivity: about 87.6 W/m·k), lithium (electrical conductivity: about 10.6×10⁶/mΩ, thermal conductivity: about 84.7 W/m·k), indium (electrical conductivity: about 11.6×10⁶/mΩ, thermal conductivity: about 81.6 W/m·k), iron (electrical conductivity: about 9.93×10⁶/mΩ, thermal conductivity: about 80.2 W/m·k), palladium (electrical conductivity: about 9.5×10⁶/mΩ, thermal conductivity: about 71.8 W/m·k), platinum (electrical conductivity: about 9.66×10⁶/mΩ, thermal conductivity: about 71.6 W/m·), and tin (electrical conductivity: about 9.17×10⁶/mΩ, thermal conductivity: about 66.6 W/m·k). These metal materials may be used singly or as a mixture of two or more kinds thereof.

The “material higher in thermal conductivity than the substrate 3” as used herein refers to any material having a thermal conductivity larger than 0.75 W/m·k since the thermal conductivity of the substrate 3 is 0.55 W/m·k to 0.75 W/m·k. Also, the “material higher in electrical conductivity than the substrate 3” as used herein refers to any material having an electrical conductivity larger than 10⁻¹⁰/mΩ since the electrical conductivity of the substrate 3 is 10⁻¹⁰/mΩ to 10⁻¹⁴/mΩ. The “thermal conductivity” as used herein refers to a value measured in conformity with JIS K6911I. The thermal conductivity, or heat conductivity, is a physical amount obtained by dividing the heat flux density (thermal energy that passes through a unit area per unit time) by the temperature gradient in thermal conduction. The relationship of the heat flux density J with the thermal conductivity λ, is expressed by J=−λgradT where T is the temperature and gradT is the temperature gradient. The “electrical conductivity” as used herein refers to a value measured in conformity with JIS K0130.

In this embodiment, from the standpoint that the conductive member 2 should have a thermal conductivity and an electrical conductivity sufficiently higher than the substrate 3, it is preferable to use a material having a thermal conductivity of 80 W/m·k or more and an electrical conductivity of 8×10⁶/mΩ or more as the material for forming the conductive member 2.

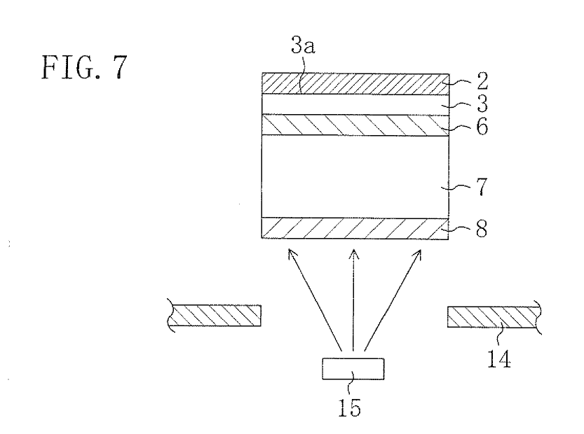

Next, an example method for fabricating the organic EL element of this embodiment will be described. FIGS. 3-7 are cross-sectional views illustrating the method for fabricating the organic EL element of this embodiment, in which FIG. 7, in particular, illustrates formation of the cathode that is the second electrode.

First, as shown in FIG. 3, the insulating substrate 3 made of glass, etc. having a size of 300×400 mm and a thickness of 0.7 mm was prepared. Aluminum higher in thermal conductivity and higher in electrical conductivity than the substrate 3 was then evaporated onto the surface 3a of the substrate 3 opposite to the surface thereof on which the first electrode 6 was to be formed, to form the conductive member 2 made of aluminum. The thickness of the conductive member 2 was 100 nm.

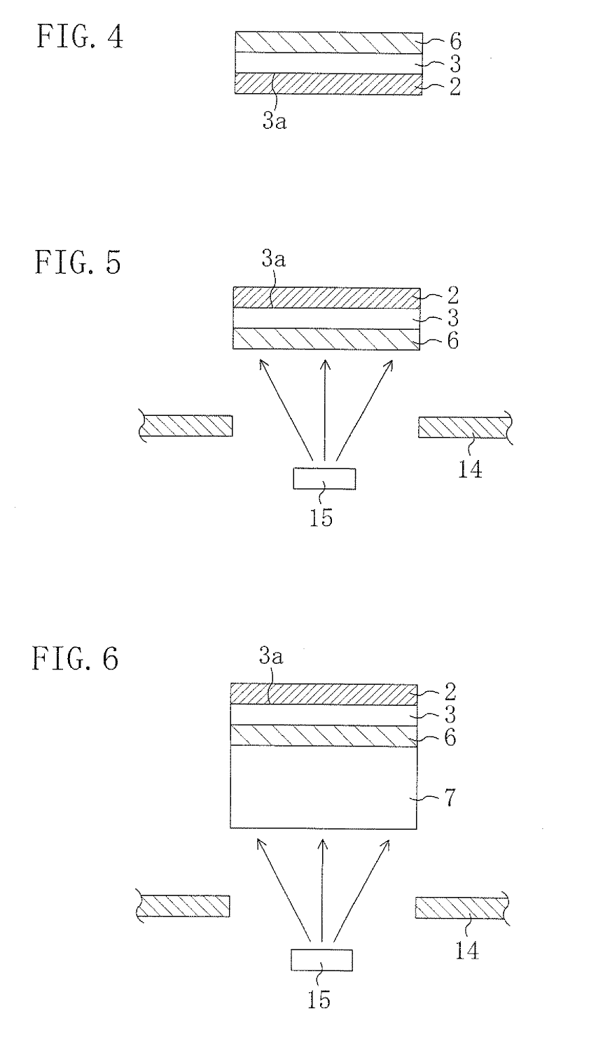

As shown in FIG. 4, an ITO film was formed into a pattern by sputtering on the surface of the substrate 3 opposite to the surface 3a on which the conductive member 2 was formed, to form the first electrode 6. The thickness of the first electrode 6 was 150 nm.

Thereafter, the organic layer 7 including the emitting layer 11 and the second electrode 8 were formed on the first electrode 6 by the vacuum evaporation method using a metal mask.

More specifically, the insulating substrate 3 with the conductive member 2 and the first electrode 6 formed thereon was placed in a chamber of an evaporation apparatus provided with an evaporation source. The inside of the chamber of the evaporation apparatus was kept at a degree of vacuum of 1×10⁻⁵ to 1×10⁻⁴ (Pa) by a vacuum pump. The substrate 3 with the conductive member 2 and the first electrode 6 formed thereon was secured, at its two sides, to a pair of substrate holders mounted in the chamber.

As shown in FIG. 5, a metal mask 14 was then secured, at its four corners, to a mask holder in the chamber. As the mask 14, used was an invar mask having a thickness of about 40 μm laser-welded to an invar frame having a thickness of about 8 mm.

Thereafter, evaporating materials for the hole injection layer 9, the hole transport layer 10, the emitting layer 11, the electron transport layer 12, and the electron injection layer 13 were sequentially evaporated from, the evaporation source 15, to have the hole injection layer 9, the hole transport layer 10, the emitting layer 11, the electron transport layer 12, and the electron injection layer 13 stacked one upon another, thereby to form the organic layer 7 on the first electrode 6 as shown in FIG. 6.

More specifically, first, the hole injection layer 9 made of 4,4,4-tris(3-methylphenylphenylamino)triphenylamine) (m-MTDATA) was formed on the first electrode 6 patterned on the insulating substrate 3, to a thickness of 25 nm via the mask 14. The hole transport layer 10 made of 4,4-bis(N-1-naphthyl-N-phenylamino)biphenyl) (α-NPD) was then formed on the hole injection layer 9 to a thickness of 30 nm via the mask 14. Subsequently, as the blue emitting layer 11, di(2-naphthyl)anthracene (AND) mixed with 2.5 wt % of 4,4′-bis[2-{4-(N,N-diphenylamino)phenyl}vinyl]biphenyl (DPAVBi) was deposited to a thickness of 30 nm via the mask 14. Thereafter, as the electron transport layer 12, 8-hydroxyquinoline aluminum (Alq3) was deposited on the emitting layer 11 to a thickness of 20 nm via the mask 14. As the electron injection layer 13, lithium fluoride (LiF) was then deposited on the electron transport layer 12 to a thickness of 0.3 nm, for example, via the mask 14.

Thereafter, lithium fluoride (LiF) and aluminum (Al) as the evaporation materials for the second electrode 8 were evaporated from the evaporation source 15 via the mask 14 to deposit these materials one upon the other, thereby to form the second electrode 8 on the organic layer 7 to a thickness of 10 nm. Thus, the organic EL element 1 shown in FIG. 1 was fabricated.

As a comparative example, an organic EL element was prepared, which was fabricated in the same manner as that in the above example except that the conductive member 2 was not formed on the surface of the substrate.

The drive voltage, the luminous efficiency, and the life were compared between the organic EL element 1 fabricated in this example and the organic EL element as the comparative example. The results are shown in Table 1, in which the drive voltage is represented by the measured voltage value [V], the luminous efficiency is represented by the measured ratio of the brightness to the current density of the element [cd/A], and the element life is represented by the measured emitting time [h]. As for the drive voltage and the luminous efficiency, the voltage was increased stepwise by 0.2 V each in the range of 0 to 15 V while the brightness was kept at 1000 cd/m², and the luminous efficiency was calculated from the current at each voltage value and the brightness. As for the element life, the time taken until the initial brightness, which was 6000 cd/m², was halved was calculated as the element life.

TABLE 1

| | Drive voltage | Luminous | Element life |
|---|---|---|---|
| | [V] | efficiency [cd/A] | [h] |
| Example | 5.67 | 4.55 | 282 |
| Comparative example | 5.98 | 4.09 | 224 |

It is found from Table 1 that, in the example in which the conductive member 2 was formed on the surface 3a of the substrate 3, the drive voltage of the organic EL element 1 can be reduced compared with the comparative example in which no conductive member was formed. It is also found that in the example, compared with the comparative example, the luminous efficiency has improved dramatically and is considerably good. Moreover, it is found that in the example, compared with the comparative example, the element life has improved dramatically, and thus the life of the organic EL element 1 can be increased.

The reason for the above is presumably that, in this example, with the formation of the conductive member 2 on the surface 3a of the substrate 3, the substrate 3 was cooled by the conductive member 2, and also static electricity in the substrate 3 was removed by the conductive member 2, during formation of the cathode as the second electrode 8 by the vacuum evaporation method.

The roundness in the shape of LiF constituting the cathode as the second electrode 8 (i.e., the roundness of the top portion of LiF) was measured for the organic EL element 1 fabricated in this example and the organic EL element of the comparative example. The results are shown in Table 2, in which the roundness in the shape of LiF was measured by measuring the load length ratio tp and the load area ratio Rmr (50%).

The load length ratio tp, defined in JIS B0601-2001, can be measured with a surface-shape measurement microscope, etc. The load length ratio tp, expressed by Equation (1) below, is obtained by extracting a predetermined reference length L from a roughness curve, determining the average height and maximum height of the extracted portion of the roughness curve, and calculating the ratio (np/L) of the sum of cut lengths (b₁, b₂, . . . , bₙ) of portions that are higher than the average height by 50% or more of the maximum height (load length np) to the reference length L expressed as a percentage.

$$tp [ \% ] = \frac{np}{L} \times 100 \qquad ( 1 )$$

where L is the reference length and np is the load length.

The load area ratio Rmr (50%) can be measured with an atomic force microscope such as Keyence VN-8000. The load area ratio Rmr (50%), expressed by Equation (2) below, is obtained by extracting a predetermined reference area S from a roughness curve, determining the average height and maximum height of the extracted portion of the roughness curve, and calculating the ratio (np/S) of the sum of cut areas (p₁, p₂, . . . , pₙ) of portions that are higher than the average height by 50% or more of the maximum height (load area np) to the reference area S expressed as a percentage.

$$Rmr ( 50 \% ) = \frac{np}{S} \times 100 \qquad ( 2 )$$

where S is the reference area and np is the load area.

TABLE 2

| | Load area ratio [%] | Load length ratio [%] |
|---|---|---|
| Example | 4.32 | 4.50 |
| Comparative example | 1.03 | 1.10 |

As shown in Table 2, both the load area ratio and the load length ratio are high in the example having the conductive member 2 formed on the surface 3a of the substrate 3, compared with the comparative example in which the conductive member 2 was not formed. It is therefore found that LiF has been formed into a round and large shape in this example.

According to the embodiment described above, the following advantages can be obtained.

(1) In this embodiment, the conductive member 2 made of a material higher in thermal conductivity and higher in electrical conductivity than the substrate 3 is formed on the surface 3a of the substrate 3 opposite to the surface on which the first electrode 6 is formed. Therefore, during formation of the second electrode 8 by a vacuum evaporation method, heat in the substrate 3 is conducted to the conductive member 2, cooling the substrate 3 by the conductive member 2. Thus, temperature rise in the substrate 3 can be suppressed or reduced. Also, during formation of the second electrode 8 by a vacuum evaporation method, since static electricity existing in the substrate 3 is removed by the conductive member 2, making the substrate free of static electricity, influence of static electricity can be prevented. This facilitates injection of a current from the organic layer 7 into the second electrode 8. Thus, the drive voltage of the organic EL element 1 can be reduced, and also the luminous efficiency of the element can be improved.

(2) With the existence of the conductive member 2 on the surface 3a of the substrate 3, the contact area of LiF with the organic layer 7 increases. Therefore, during injection of a current from the organic layer 7 into the second electrode 8, the current density per unit area decreases, permitting dispersed injection of the current into the second electrode 6. Thus, current-caused degradation is reduced, and as a result, the life of the organic EL element 1 can be increased.

(3) In this embodiment, the thermal conductivity of the material for forming the conductive member 2 is set to 80 W/m·k or more, and the electrical conductivity thereof is set to 8×10⁶/mΩ or more. Therefore, with the conductive member 2 sufficiently higher in thermal conductivity and electrical conductivity than the substrate 3, it is ensured that temperature rise in the substrate 3 can be suppressed or reduced, and also influence of static electricity can be prevented, during formation of the second electrode 8 by a vacuum evaporation method.

(4) In this embodiment, the material for forming the conductive member 2 is metal. Therefore, the thermal conductivity and electrical conductivity of the conductive member 2 can be easily improved.

(5) In this embodiment, as the metal for forming the conductive member 2, any of the following metals is used: silver, copper, gold, aluminum, calcium, tungsten, magnesium, rhodium, iridium, sodium, molybdenum, ruthenium, zinc, cobalt, cadmium, nickel, osmium, lithium, indium, and iron. Therefore, the conductive member 2 can be formed of an inexpensive and versatile material.

The embodiment described above may be modified as follows.

Although metal is used as the material for forming the conductive member 2 in the above embodiment, a material other than metal may be used. That is, it is possible to use any material that has a thermal conductivity and electrical conductivity higher than the substrate, and specifically has a thermal conductivity of 80 W/m·k or more and an electrical conductivity of 8×10⁶/mΩ or more. For example, a conductive resin may be used for forming the conductive member 2.

### INDUSTRIAL APPLICABILITY

As described above, the present disclosure is particularly useful in an organic EL element of which the second electrode is formed by a vacuum evaporation method, and a method for fabricating the same.

### DESCRIPTION OF REFERENCE CHARACTERS

1 Organic EL Element
2 Conductive Member
3 Substrate
6 First Electrode
7 Organic Layer
8 Second Electrode
11 Emitting Layer
1 Mask

1. An organic El element, comprising:
a substrate;
a first electrode formed on the substrate;
an organic layer having an emitting layer, formed on the first electrode; and
a second electrode formed on the organic layer,
wherein
a conductive member made of a material higher in thermal conductivity and higher in electrical conductivity than the substrate is formed on a surface of the substrate opposite to a surface on which the first electrode is formed.

2. The organic EL element of claim 1, wherein the thermal conductivity is 80 W/m·k or more and the electrical conductivity is 8×10⁶/mΩ or more.

3. The organic EL element of claim 1, wherein the material is metal.

4. The organic EL element of claim 3, wherein the metal is at least one kind selected from the group consisting of silver, copper, gold, aluminum, calcium, tungsten, magnesium, rhodium, iridium, sodium, molybdenum, ruthenium, zinc, cobalt, cadmium, nickel, osmium, lithium, indium, and iron.

5. A method for fabricating an organic EL element including a first electrode, an organic layer having an emitting layer, and a second electrode formed in this order on a substrate, the method comprising the steps of:
forming a conductive member on a surface of the substrate, the conductive member being made of a material higher in thermal conductivity and higher in electrical conductivity than the substrate;
forming the first electrode on a surface of the substrate opposite to the surface on which the conductive member is formed; and
forming the organic layer on the first electrode, and then forming the second electrode on the organic layer, by a vacuum evaporation method using a mask.

6. The method for fabricating an organic EL element of claim 5, wherein the thermal conductivity is 80 W/m·k or more and the electrical conductivity is 8×10⁶/mΩ or more.

7. The method for fabricating an organic EL element of claim 5, wherein the material is metal.

8. The method for fabricating an organic EL element of claim 7, wherein the metal is at least one kind selected from the group consisting of silver, copper, gold, aluminum, calcium, tungsten, magnesium, rhodium, iridium, sodium, molybdenum, ruthenium, zinc, cobalt, cadmium, nickel, osmium, lithium, indium, and iron.
